(19) United States
(12) Patent Application Publication
(10) Pub. No.: US 2005/0139769 A1
(43) Pub. Date: Jun. 30, 2005

(54) Solid state imaging device

(76) Inventors: Hiroaki Kita, Kagoshima (JP); Takeshi Miyata, Kagoshima (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/003,628

(22) Filed: Dec. 3, 2004

(30) Foreign Application Priority Data
Dec. 10, 2003 (JP) JP2003-411261

(51) Int. Cl. G01N 23/00; H01L 21/8238

(52) U.S. Cl. 250/310; 250/311

(57) ABSTRACT

The present invention provides a solid state imaging device capable of avoiding noises caused by the dark current from appearing on an image. According to the present invention, a device separation area is provided around each pixel area, and an electrode is provided on a surface of the device separation area, and further, a drain is provided near the electrode of the device separation area for discharging unnecessary electrons generated at the device separation area.

### CROSS REFERENCE TO RELATED APPLICATION

This application claims priority from Japanese Priority Document No. 2003-411261, filed on Dec. 10, 2003 with the Japanese Patent Office, which document is hereby incorporated by reference.

### BACKGROUND OF THE INVENTION

1. Field of the Invention

The present invention relates to a solid state imaging device having a device separation area provided around a pixel area, and an electrode provided on a surface of the device separation area.

2. Description of Related Art

Conventionally, an imaging apparatus such as a video camera, an electronic digital still camera, and the like has employed a solid state imaging device.

In a conventional solid state imaging device 100, each pixel area 103 was configured with a photo diode 101, and a register 102, as shown in FIGS. 2 and 3, and a device separation area 105 was further formed around the pixel area 103.

The above mentioned device separation area 105 was formed with a P type diffusion area provided at a predetermined position of a P well 106, and as the P type diffusion area became an electric potential barrier between the pixel area 103 and the peripheral devices, this P type diffusion area was configured to electrically isolate the pixel area 103 and the peripheral devices.

In addition, on the surface of the device separation area 105, a metal electrode 107 was connected, and a potential of the device separation area 105 was fixed to be a ground potential by connecting the metal electrode 107 to the ground.

As described above, in the above mentioned conventional solid state imaging device 100, the positive holes generated at the photo diode 101 were discharged outside the pixel area 103 by connecting the metal electrode 107 to the ground (see Patent Document: Japanese Laid-Open Patent H11-177078, for example).

### SUMMARY OF THE INVENTION

In the solid state imaging device 100 of this conventional example, after the insulating film 108 was formed on the surface of the device separation area 105, the surface of the device separation area 105 was partially exposed to outside by etching a predetermined position of the insulating film 108, and after that, the metal electrode 107 was connected to the exposed surface of the device separation area 105.

However, in this conventional solid state imaging device 100, the surface of the device separation area 105 was exposed to outside by etching a predetermined position of the insulating film 108 when forming the metal electrode 107 on the surface of the device separation area 105 as described above.

On this account, some crystal defects were occurred on the surface of the device separation area 105 due to damages by aforementioned etching, and accordingly, there was the threat that unnecessary electrons caused by the crystal defects would mix in the pixel area 103 as a dark current.

Thus, if such dark current gets mixed into the pixel area 103, not only electrons obtained by photoelectric conversion of an incoming light, but also such unnecessary electrons by the dark current were resultantly accumulated in the photo diode 101 and the register 102.

Accordingly, there was the threat that when the thus accumulated electrons were read out from a transfer electrode as a video signal, the unnecessary electrons by the dark current would appear on an image as noises.

According to an embodiment of the present invention, a device separation area is provided around each pixel area, and an electrode is provided on a surface of the device separation area, wherein a drain is provided near the electrode in order to discharge electrons generated at the device separation area

According to the embodiment of the present invention, the drain is provided adjacent to the device separation area provided next to a photo diode configuring the pixel area.

According to the embodiment of the present invention, the drain is provided next to an ohmic area which performs ohmic junction between the electrode and the device separation area.

The embodiment of the present invention has following advantages.

According to the first aspect of the present invention, in the solid state imaging device having the device separation area provided around the pixel area and the electrode provided on the surface of the device separation area, the drain for discharging the electrons generated at the device separation area is formed near the electrode. Accordingly, unnecessary electrons generated on the surface of the device separation area due to crystal defects are to be discharged to the drain side without mixing into the pixel area, so that it is able to prevent the generation of dark currents caused by the crystal defects in the device separation area.

Further, according to the second aspect of the present invention, the drain is provided adjacent to the device separation area provided next to each photo diode forming the pixel area, so that it is able to prevent the unnecessary electrons generated near the surface of the device separation area from mixing into the photo diode.

Still further, according to the third aspect of the present invention, the drain is provided adjacent to the ohmic area for performing the ohmic junction between the electrode and the device separation area, so that it is able to discharge the unnecessary electrons to outside of the pixel area from neighbors of the ohmic area where the crystal defects tend to occur.

### BRIEF DESCRIPTION OF THE DRAWINGS

FIG. 1 is an explanatory sectional view for describing one embodiment of a solid state imaging device according to the present invention;

FIG. 2 is a top view of the embodiment of the present invention in FIG. 1, wherein A-A shows a sectional line for the sectional view in FIG. 1;

FIG. 3 is an explanatory sectional view for describing a conventional solid state imaging device; and

FIG. 4 is a top view of the conventional solid state imaging device in FIG. 3, wherein B-B shows a sectional line for the sectional view in FIG. 3.

### DETAILED DESCRIPTION OF THE PREFERRED EMBODIMENT

A solid state imaging device of the present invention includes a photo diode for converting an incoming light into electrons and positive holes and for accumulating the electrons for a predetermined time, and a register for reading out the electrons thus accumulated in the photo diode as an electrical video signal. In this case, one pixel area is configured to include the photo diode and the register.

A device separation area is further provided around the pixel area in order to electrically isolate the pixel area and peripheral devices.

This device separation area is formed with an impurity diffused area provided around the pixel area, and this impurity diffused area becomes an electrical potential barrier between the pixel area and the peripheral devices, so that the pixel area and the peripheral devices are electrically isolated to each other.

At a predetermined position of the surface side of the device separation area, an ohmic area in which an impurity is highly diffused is provided, and a metal electrode is provided on the surface of the ohmic area.

By attaching the metal electrode on the surface of the ohmic area where the impurity is highly diffused, the ohmic area and the metal electrode are connected by the ohmic junction.

In addition, the metal electrode is grounded to fix the potential of the device separation area to the ground potential, so that it is so arranged as to discharge the positive holes generated at the photo diode to outside of the pixel area,

Further, a drain is provided near the metal electrode, and this drain has a conduction type opposite to the conduction type of the impurity diffused area which forms the device separation area.

As described above, by providing the drain near the metal electrode, it becomes possible to discharge the unnecessary electrons generated at the surface of the device separation area due to the crystal defects to the drain side.

It is clear that this technology dose not depend on a fabrication process for CCD, CMOS, etc., and the present invention is applicable to a solid state imaging device which at least includes a photo diode, a device separation area, and a metal electrode on a surface thereof.

Thereby, the unnecessary electrons generated near the surface of the device separation area do not get mixed into the pixel area as dark current, so that it is able to prevent noises caused by the dark current from appearing on the display image before happens.

In addition, the drain is provided adjacent to the device separation area formed next to the photo diode to accumulate only necessary electrons obtained by converting the incoming light, so that it is able to make the quality of the display image much better.

Further, the drain is provided adjacent to the ohmic area so as to be able to discharge, to outside of the pixel area, the unnecessary electrons from an area near the junction between the ohmic area and the metal electrode where the crystal defects tend to occur, so that it is able to prevent the noises caused by the dark current from appearing on the display image before happens.

Hereinafter, one embodiment of a solid state imaging device of the present invention is described with reference to the attached drawings.

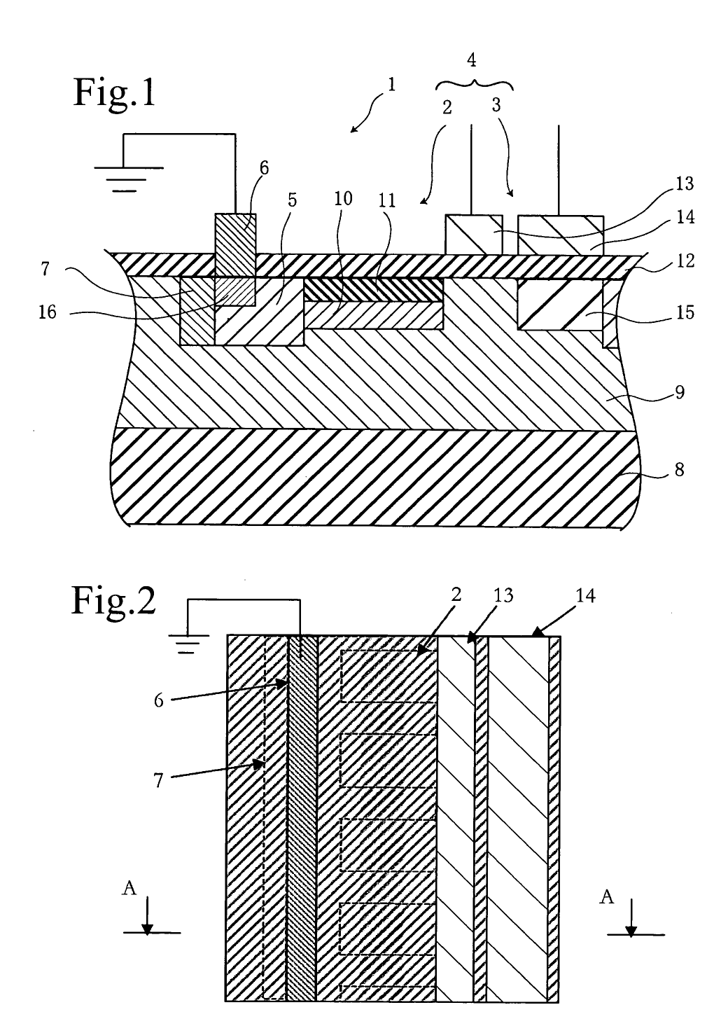

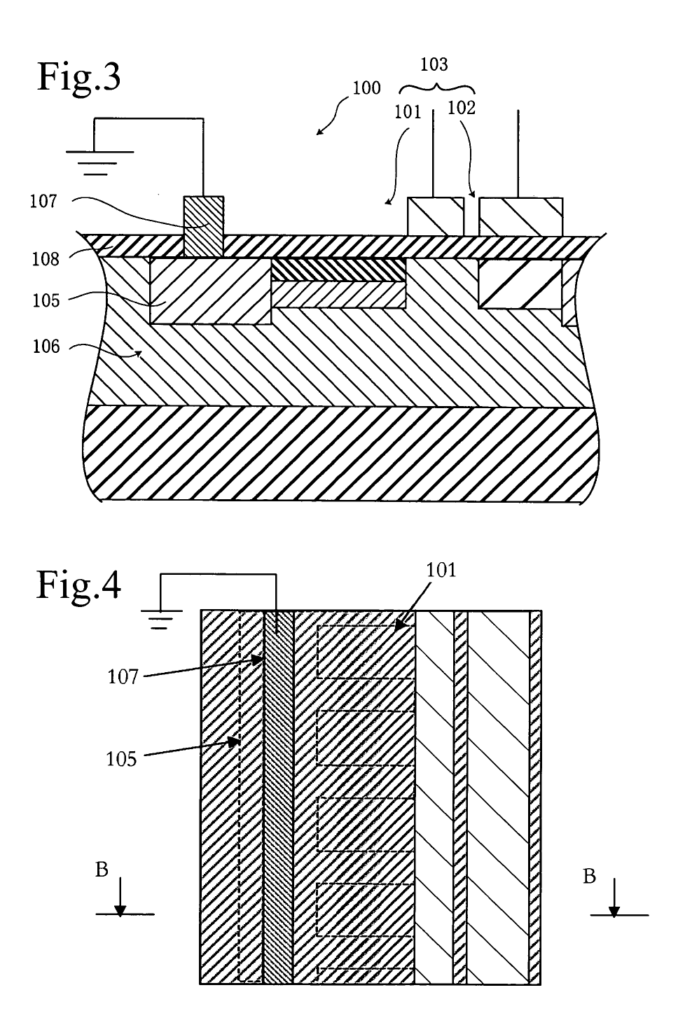

A solid state imaging device 1 includes, as shown in FIG. 1 and FIG. 2, a pixel area 4 formed by a photo diode 2 and a register 3, a device separation area 5 provided around the pixel area 4, a metal electrode 6 connected to the device separation area 5, and a drain 7 provided near the metal electrode 6.

The photo diode 2 is formed with a P well 9 of a P type diffusion area provided on the surface of the N type semiconductor substrate 8, an N type diffusion layer 10 provided at the surface side of the P well 9, and a P type diffusion layer 11 provided on a surface of the N type diffusion layer.

When a light of an object is incident on the photo diode 2, the light is converted into an electric signal by the photo diode 2, electron-positive hole pairs are generated at a depletion layer of a PN junction in the photo diode 2, and only the electrons of the electron-positive hole pairs are accumulated for a predetermined time in the photo diode 2.

On the contrary, the positive holes have a characteristic to move to a low potential, so that the generated positive holes are discharged to outside of the pixel area 4 via a later described metal electrode 6.

The register 3 is formed with a readout electrode 13 and a transfer electrode 14 both being provided on a predetermined position at a surface of the P well 9 via the insulating film 12, and an N type buried channel 15 provided at the P well 9 immediately beneath the transfer electrode 14.

Then, by applying a voltage to the readout electrode 13, the electrons accumulated in the photo diode 2 are transferred to the N type buried channel 15, and thus transferred electrons to this N type buried channel 15 are arranged to be outputted from the transfer electrode 14 as an electrical image signal.

The device separation area 5 is formed with the P type diffusion area having a conduction type opposite to those of the N type diffusion layer 10 of the photo diode 2, and the N type buried channel 15 of the register 3, and is able to electrically isolate the pixel area 4 from the peripheral devices, because the P type diffusion area serves as an electrical potential barrier between the pixel area 4 and the peripheral devices.

A surface of the device separation area 5 is exposed to outside by etching a predetermined portion of an insulating film 12 provided on the surface of the device separation area 5, and the metal electrode 6 is configured to attach on the exposed surface of the device separation area 5.

Further, near the surface of the device separation area 5 bonding with the metal electrode 6, an ohmic area 16 to which a P type impurity is highly diffused higher than the device separation area 5 is provided, so that the device separation area 5 and the metal electrode 6 are connected by the ohmic junction.

In this case, the metal electrode 6 is connected to ground to fix the potential of the device separation area 5 to the ground potential, thereby the positive holes generated at the photo diode 2 are discharged to outside of the pixel area 4.

The drain 7 is configured with the N type diffuision area provided near the junction between the device separation area 5 and the metal electrode 6, and is arranged to discharge to outside of the pixel area 4 the unnecessary electrons generated regardless of the light incident on the solid state imaging device 1 such as electrons generated due to the crystal defects of the junction between the device separation area 5 and the metal electrode 6.

That is, the unnecessary electrons generated due to the crystal defects of the junction between the device separation area 5 and the metal electrode 6 are not able to exceed the electrical potential barrier of the device separation area 5, and do not get mixed into the pixel area 4, so that it is arranged to discharge these unnecessary electrons to the drain 7 side where there is no electrical potential barrier.

For the sake, the unnecessary electrons does not get mixed into the pixel area 4 as the dark current, and accordingly, it is able to prevent the noises caused by the dark current from appearing on the display image before happens.

Further, the drain 7 is provided adjacent to the ohmic area 16 at the device separation area 5 provided next to the photo diode 2, so that it is possible to intensively discharge, to outside of the pixel area 4, the unnecessary electrons near the junction between the ohmic area 16 and the metal electrode 6 where the crystal defects tend to occur. Accordingly, it is able to prevent the noises caused by the dark current from appearing on the display image before happens.

1. A solid state imaging device including an electrode on a surface of a device separation area provided around each pixel area, comprising:
a drain provided near said electrode for discharging electrons generated at said device separation area.

2. The solid state imaging device as cited in claim 1, wherein
said drain is provided adjacent to said device separation area which is located adjacent to a photo diode forming said pixel area.

3. The solid state imaging device as cited in claim 1, or claim 2 wherein
said drain is provided adjacent to an ohmic area for performing an ohmic junction between said electrode and said device separation area.
